(19) United States
(12) Patent Application Publication
(10) Pub. No.: US 2026/0047308 A1
(43) Pub. Date: Feb. 12, 2026

(54) DISPLAY DEVICE AND ELECTRONIC DEVICE INCLUDING THE SAME

(71) Applicant: Samsung Display Co., Ltd., Yongin-Si (KR)

(72) Inventors: GI-NA YOO, Yongin-si (KR); Jiyoung Kim, Yongin-si (KR); SIJIN SUNG, Yongin-si (KR)

(21) Appl. No.: 19/085,761

(22) Filed: Mar. 20, 2025

(30) Foreign Application Priority Data
Aug. 6, 2024 (KR) 10-2024-0104713

(51) Int. Cl. H10K 59/40; G06F 3/041; G09G 3/3233; H10K 59/122; H10K 59/35

(52) U.S. Cl. CPC H10K 59/40; G06F 3/0412; H10K 59/122; G09G 3/3233; G09G 2300/0426; G09G 2300/0842; H10K 59/352

(57) ABSTRACT

Provided are a display device and an electronic device including the same. The display device includes a substrate, a light-emitting element layer disposed on the substrate, the light-emitting element layer including a plurality of emission areas and a pixel defining layer defining the plurality of emission areas, a first touch electrode disposed on the light-emitting element layer to overlap the pixel defining layer, a first insulating layer disposed on the first touch electrode and the light-emitting element layer, and a second touch electrode disposed on the first insulating layer to overlap the pixel defining layer. A distance between one surface of the substrate and the second touch electrode varies depending on a width of the pixel defining layer on which the second touch electrode is disposed.

### CROSS-REFERENCE TO RELATED APPLICATION

This application is based on and claims priority under 35 U.S.C. § 119 to Korean Patent Application No. 10-2024-0104713, filed on Aug. 6, 2024, in the Korean Intellectual Property Office, the disclosure of which is incorporated by reference herein in its entirety.

### BACKGROUND

### 1. Field

One or more embodiments relate to a display device and an electronic device including the same.

### 2. Description of the Related Art

Organic light-emitting display devices have self-luminescence properties and do not require a separate light source, unlike liquid crystal display devices. Accordingly, the thickness and weight of the organic light-emitting display devices may be reduced. In addition, the organic light-emitting display devices exhibit high quality characteristics, such as low power consumption, high luminance, and fast response time.

Recent display devices support input using a part of a user's body (e.g., a finger) and input using an input pen. By sensing input using an input pen, display devices may sense input with higher precision than when only using input using a part of a user's body.

### SUMMARY

One or more embodiments provide a display device with improved side visibility.

However, this is only an example, and the technical problems to be solved by the disclosure are not limited thereto.

Additional aspects will be set forth in part in the description which follows and, in part, will be apparent from the description, or may be learned by practice of the presented embodiments of the disclosure.

According to one or more embodiments, a display device includes a substrate, a light-emitting element layer disposed on the substrate, the light-emitting element layer including a plurality of emission areas and a pixel defining layer defining the plurality of emission areas, a first touch electrode disposed on the light-emitting element layer to overlap the pixel defining layer, a first insulating layer disposed on the first touch electrode and the light-emitting element layer, and a second touch electrode disposed on the first insulating layer to overlap the pixel defining layer. A distance between one surface of the substrate and the second touch electrode varies depending on a width of the pixel defining layer on which the second touch electrode is disposed.

In an embodiment, the width of the pixel defining layer may be defined as a distance between one emission area and another adjacent emission area, and a thickness of the first insulating layer corresponding to an area where the second touch electrode is disposed may be proportional to the width of the pixel defining layer in an area corresponding to the second touch electrode.

In an embodiment, the first insulating layer may include a first area corresponding to the emission area and a second area corresponding to the pixel defining layer, and a thickness of the second area may be different from a thickness of the first area.

In an embodiment, the display device may further include a protective layer covering the second touch electrode and the first insulating layer. A refractive index of the protective layer may be higher than a refractive index of the first insulating layer.

In an embodiment, a width of the second area may be proportional to the width of the pixel defining layer.

In an embodiment, the width of the second area may be equal to or greater than twice a width of the second touch electrode and equal to or less than the width of the pixel defining layer.

In an embodiment, the display device may further include an encapsulation layer covering the light-emitting element layer. The first touch electrode may be disposed on the encapsulation layer.

In an embodiment, the plurality of emission areas may include a first emission area configured to emit light of a first color, a second emission area configured to emit light of a second color different from the first color, and a third emission area configured to emit light of a third color different from the first and second colors. The first emission area, the second emission area, and the third emission area may have different areas from each other.

In an embodiment, the first emission area may be configured to emit red light, the second emission area may be configured to emit green light, the third emission area may be configured to emit blue light, the first emission area may be disposed adjacent to the second emission area in a first direction, and the third emission area may be disposed adjacent to each of the first emission area and the second emission area in a second direction. The first direction and the second direction may be different.

In an embodiment, the width of the pixel defining layer between the first emission area and the third emission area or between the second emission area and the third emission area may be narrower than the width of the pixel defining layer between the third emission area and another third emission area.

In an embodiment, a maximum thickness of the first insulating layer may be equal to or less than twice a minimum thickness of the first insulating layer.

According to one or more embodiments, an electronic device includes a display module including a light-emitting element layer including a plurality of emission areas and a pixel defining layer defining the plurality of emission areas, a first touch electrode disposed on the light-emitting element layer to overlap the pixel defining layer, a first insulating layer disposed on the first touch electrode and the light-emitting element layer, and a second touch electrode disposed on the first insulating layer to overlap the pixel defining layer. A height at which the second touch electrode is disposed varies depending on a width of the pixel defining layer on which the second touch electrode is disposed. The electronic device further includes a memory configured to store at least one command for sensing touch input, and a processor configured to operate with reference to the memory and sense a touch position based on sensing data sensed through the first touch electrode and the second touch electrode.

In an embodiment, the width of the pixel defining layer may be defined as a distance between one emission area and another adjacent emission area, and a thickness of the first insulating layer corresponding to an area where the second touch electrode is disposed may be proportional to the width of the pixel defining layer in an area corresponding to the second touch electrode.

In an embodiment, the first insulating layer may include a first area corresponding to the emission area and a second area corresponding to the pixel defining layer, and a thickness of the second area may be different from a thickness of the first area.

In an embodiment, the electronic device may further include a protective layer covering the second touch electrode and the first insulating layer. A refractive index of the protective layer may be higher than a refractive index of the first insulating layer.

In an embodiment, a width of the second area may be proportional to the width of the pixel defining layer.

In an embodiment, the width of the second area may be equal to or greater than twice a width of the second touch electrode and equal to or less than the width of the pixel defining layer.

In an embodiment, the plurality of emission areas may include a first emission area configured to emit light of a first color, a second emission area configured to emit light of a second color different from the first color, and a third emission area configured to emit light of a third color different from the first and second colors, and the first emission area, the second emission area, and the third emission area may have different areas from each other.

In an embodiment, the first emission area may be configured to emit red light, the second emission area may be configured to emit green light, the third emission area may be configured to emit blue light, the first emission area may be disposed adjacent to the second emission area in a first direction, and the third emission area may be disposed adjacent to each of the first emission area and the second emission area in a second direction. The first direction and the second direction may be different.

In an embodiment, the width of the pixel defining layer between the first emission area and the third emission area or between the second emission area and the third emission area may be narrower than the width of the pixel defining layer between the third emission area and another third emission area.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display device according to an embodiment.

FIG. 2 is a schematic circuit diagram of a display element and a pixel circuit connected thereto in a pixel of a display device according to an embodiment.

FIG. 3 is a schematic cross-sectional view of a display device according to an embodiment.

FIG. 4 is a schematic plan view of a display device according to an embodiment.

FIG. 5 is a schematic enlarged view of a region A of FIG. 4.

FIG. 6 is a schematic cross-sectional view illustrating an example of the cross-section of the display device taken along line II-II′ of FIG. 5.

FIG. 7 is a schematic cross-sectional view illustrating an example of the cross-section of the display device taken along line III-III′ of FIG. 5.

FIG. 8 is a schematic cross-sectional view illustrating an example of the cross-section of the display device taken along line III-III′ of FIG. 5.

FIG. 9 is a schematic cross-sectional view illustrating an example of the cross-section of the display device taken along line III-III′ of FIG. 5.

FIG. 10 is a schematic cross-sectional view illustrating an example of the cross-section of the display device taken along line III-III′ of FIG. 5.

FIG. 11 is a schematic cross-sectional view illustrating an example of the cross-section of the display device taken along line III-III′ of FIG. 5.

FIG. 12 is a schematic cross-sectional view illustrating an example of the cross-section of the display device taken along line IV-IV′ of FIG. 5.

FIG. 13 is a schematic cross-sectional view illustrating an example of the cross-section of the display device taken along line IV-IV′ of FIG. 5.

FIG. 14 is a schematic plan view of a display device according to an embodiment.

FIG. 15 is a graph showing color coordinates with respect to a measurement angle of white light in a display device according to a comparative example.

FIG. 16 is a graph showing color coordinates with respect to a measurement angle of white light in a display device according to an embodiment.

FIG. 17 is a graph showing ASymmetry Color Shift (ASCS) with respect to a change in thickness of a first insulating layer in a display device according to an embodiment.

FIG. 18 is a diagram for comparing and describing distances between emission areas in the display device of FIG. 14.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, the disclosure is not limited to the following embodiments and may be embodied in various forms.

In the following embodiments, the terms “first,” “second,” etc. are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the following embodiments, it will be understood that, when a portion such as unit, region, or element is referred to as being “on” another portion, this may include not only a case where the portion is directly on the other portion, but also a case where intervening units, regions, or elements may be present therebetween.

In the following embodiments, it will be understood that the terms “connection” or “coupling” do not necessarily mean “direct and/or fixed connection or coupling” of two members, unless the context clearly indicates otherwise, and this does not preclude the arrangement of other members between the two members.

Also, sizes of elements in the drawings may be exaggerated or reduced for convenience of explanation. For example, because sizes and/or thicknesses of elements in the drawings are arbitrarily illustrated for convenience of explanation, the disclosure is not limited thereto.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

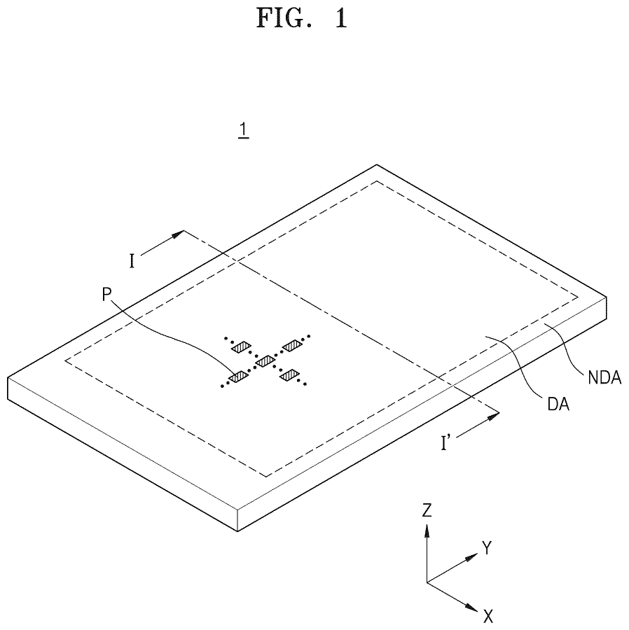

FIG. 1 is a schematic perspective view of a display device 1 according to an embodiment.

Referring of FIG. 1, the display device 1 according to an embodiment may include a display area DA and a non-display area NDA outside the display area DA. Although FIG. 1 illustrates that the display area DA has an approximately rectangular shape, the disclosure is not limited thereto. The display area DA may have various shapes, such as a circular shape, an elliptical shape, or a polygonal shape.

The display area DA is an area in which an image is displayed, and a plurality of pixels P may be disposed in the display area DA. Hereinafter, in the present specification, a “pixel” may refer to a “sub-pixel.” Each of the pixels P may include a light-emitting element, such as an organic light-emitting diode. Each of the pixels P may emit, for example, red light, green light, blue light, or white light.

The display area DA may be configured to provide a certain image through pieces of light emitted from the pixels P. The pixel P as used herein may be defined as an emission area configured to emit any one of red light, green light, blue light, and white light, as described above.

The non-display area NDA may be an area in which the pixels P are not disposed, and thus, an image is not displayed. Power supply lines configured to drive the pixels P, a terminal portion to which a printed circuit board or a driver integrated circuit (IC) including a driving circuit is connected, and the like may be disposed in the non-display area NDA.

Hereinafter, an organic light-emitting display device is described as an example of the display device 1 according to an embodiment. However, the display device 1 according to an embodiment is not limited thereto. The display device 1 according to an embodiment may be an inorganic light-emitting display (or an inorganic electroluminescence (EL) display), a quantum dot light-emitting display, or the like. For example, an emission layer of a light-emitting element included in the display device 1 may include an organic material or an inorganic material. Quantum dots may be disposed on a path of light emitted from the emission layer.

In addition, the display device 1 according to an embodiment may be applied to portable electronic devices, such as mobile phones, smartphones, tablet personal computers (PCs), mobile communication terminals, electronic organizers, e-books, portable multimedia players (PMPs), navigation systems, and ultra mobile PCs (UMPCs). Also, the display device 1 according to an embodiment may be applied to various products, such as televisions, laptops, monitors, billboards, and Internet of things (IoT) devices. The display device 1 according to an embodiment may also be applied to wearable devices, such as smart watches, watch phones, glasses-type displays, and head mounted displays (HMDs). The display device 1 according to an embodiment may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles.

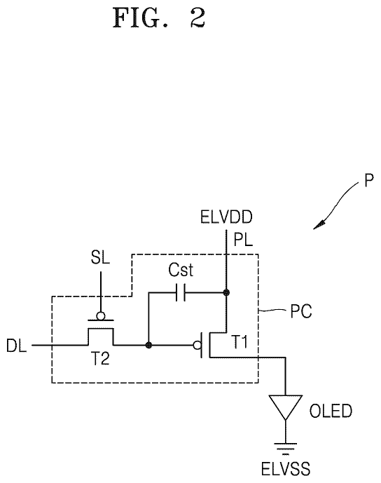

FIG. 2 is a schematic circuit diagram of a display element and a pixel circuit connected thereto in a pixel of a display device according to an embodiment.

Referring to FIG. 2, an organic light-emitting diode OLED, which is a display element, may be connected to a pixel circuit PC. The pixel circuit PC may include a first thin-film transistor T1, a second thin-film transistor T2, and a storage capacitor Cst. The organic light-emitting diode OLED may be configured to emit, for example, red light, green light, or blue light, or may be configured to emit, for example, red light, green light, blue light, or white light.

The second thin-film transistor T2, which acts as a switching thin-film transistor, may be connected to a scan line SL and a data line DL and may be configured to transmit, to the first thin-film transistor T1, a data voltage input from the data line DL in response to a switching voltage input from the scan line SL. The storage capacitor Cst may be connected to the second thin-film transistor T2 and a driving voltage line PL and may be configured to store a voltage corresponding to a difference between a voltage received from the second thin-film transistor T2 and a first power supply voltage ELVDD supplied to the driving voltage line PL.

The first thin-film transistor T1, which acts as a driving thin-film transistor, may be connected to the driving voltage line PL and the storage capacitor Cst and may be configured to control a driving current flowing from the driving voltage line PL to the organic light-emitting diode OLED according to a voltage value stored in the storage capacitor Cst. The organic light-emitting diode OLED may be configured to emit light with a certain luminance according to the driving current. An opposite electrode (e.g., a cathode) of the organic light-emitting diode OLED may be configured to receive a second power supply voltage ELVSS.

FIG. 2 illustrates that the pixel circuit PC includes two thin-film transistors and one storage capacitor, but in an embodiment, the number of thin-film transistors or the number of storage capacitors may be variously changed according to the design of the pixel circuit PC.

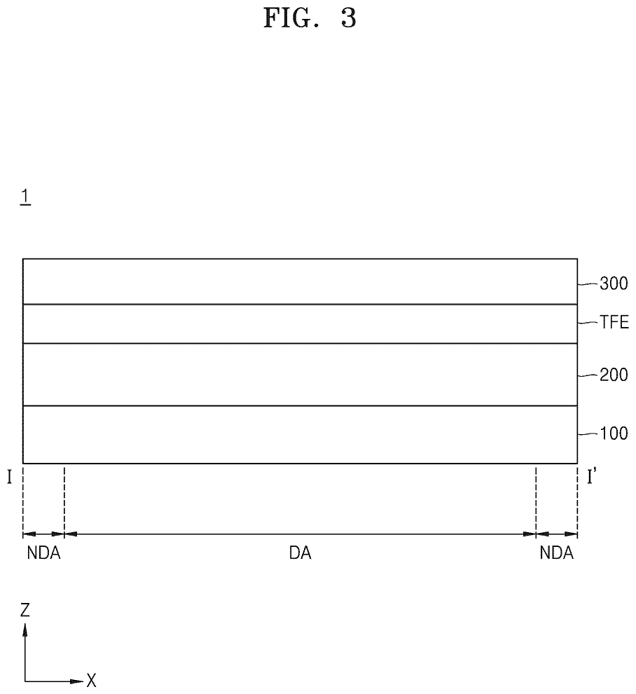

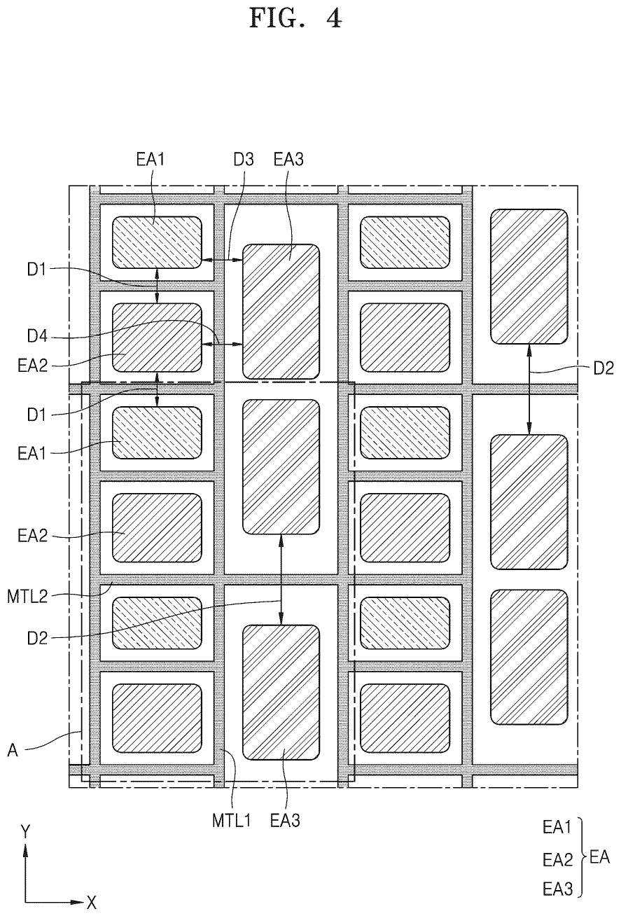

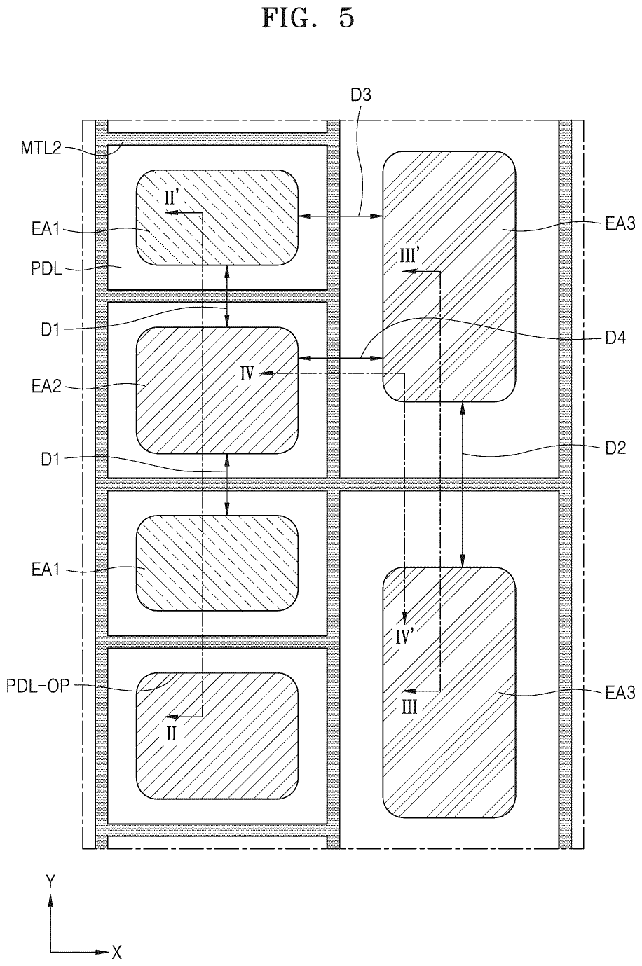

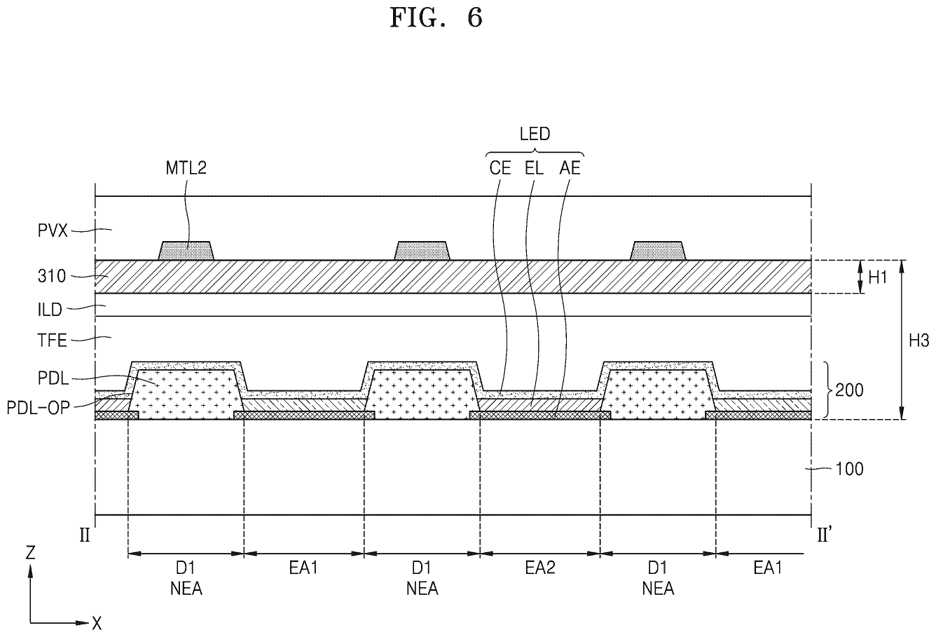

FIG. 3 is a schematic cross-sectional view of the display device 1 according to an embodiment. FIG. 3 is a cross-sectional view of the display device 1 taken along line I-I′ of FIG. 1. FIG. 4 is a schematic plan view of the display device 1 according to an embodiment. FIG. 5 is a schematic enlarged view of a region A of FIG. 4, and FIG. 6 is a schematic cross-sectional view illustrating an example of the cross-section of the display device 1 taken along line II-II′ of FIG. 5.

Referring to FIGS. 3 to 6, the display device 1 according to an embodiment may include a substrate 100, a light-emitting element layer 200, a thin-film encapsulation layer TFE, and a touch sensing layer 300.

The display device 1 according to an embodiment may include the substrate 100, a plurality of pixel electrodes on the substrate 100, a first touch electrode MTL1 on the pixel electrodes, a first insulating layer 310 covering the first touch electrode MTL1, a second touch electrode MTL2 on the first insulating layer 310, and a protective layer PVX covering the second touch electrode MTL2.

The substrate 100 may include various materials, for example, glass, metal, or plastic, such as polyethylene terephthalate (PET), polyethylene naphthalate (PEN), or polyimide. The substrate 100 including polymer resin may be flexible, rollable, or bendable. The substrate 100 may have a multilayer structure including a polymer resin-containing layer (not shown) and an inorganic layer (not shown).

Although not illustrated, a circuit layer including thin-film transistors may be disposed on the substrate 100. The thin-film transistors may be disposed on the substrate 100, a planarization layer may cover the thin-film transistors, and a plurality of pixel electrodes may be disposed on the planarization layer.

Each of the thin-film transistors may include a semiconductor region, a source electrode, a drain electrode, and a gate electrode. For example, when a gate driver is formed on one side of the non-display area NDA of the display device 1, the gate driver may include thin-film transistors.

The substrate 100 may have a display area in which a plurality of pixel electrodes is disposed and a peripheral area surrounding the display area.

That is, the pixel electrodes may be disposed on the substrate 100. The expression “the pixel electrodes are disposed on the substrate 100” may include not only a case where the pixel electrodes are directly disposed on the substrate 100, but also a case where various layers are formed on the substrate 100 and the pixel electrodes are disposed on the various layers. For example, as described above, the thin-film transistors may be disposed on the substrate 100, the planarization layer may be formed to cover the thin-film transistors, and the pixel electrodes may be disposed on the planarization layer. In FIG. 6, for convenience, the pixel electrodes are illustrated as being directly disposed on the substrate 100. The following description is given focusing on such a case for convenience.

The light-emitting element layer 200 may be disposed on the substrate 100. Specifically, the light-emitting element layer 200 may be disposed on the circuit layer including the thin-film transistors.

The light-emitting element layer 200 may include a plurality of light-emitting elements LED that emit light and a pixel defining layer PDL that defines pixels. Each of the light-emitting elements LED may include a first electrode AE, an emission layer EL, and a second electrode CE, which are sequentially stacked in this stated order. The first electrode AE may be a pixel electrode described above and the second electrode CE may be a common electrode.

The light-emitting element layer 200 may include a plurality of emission areas and a pixel defining layer PDL defining the emission areas.

The light-emitting elements of the light-emitting element layer 200 may be disposed in the display area DA.

For example, the emission layer EL may be an organic light-emitting layer including an organic material. The emission layer EL may include a hole transporting layer, an organic light-emitting layer, and an electron transporting layer. When the first electrode AE receives a certain voltage through the thin-film transistor of the circuit layer and the second electrode CE receives a common voltage, holes and electrons may move to the organic light-emitting layer through the hole transporting layer and the electron transporting layer, respectively, and recombine with each other in the organic light-emitting layer to emit light. For example, the first electrode AE may be an anode electrode and the second electrode CE may be a cathode electrode, but the disclosure is not limited thereto.

As an example, each of the light-emitting elements LED may include a quantum dot light-emitting diode including a quantum dot light-emitting layer, an inorganic light-emitting diode including an inorganic semiconductor, or a micro light-emitting diode.

The pixel defining layer PDL covering edges of each of the first electrodes AE to expose a central portion of each of the first electrodes AE may be disposed on the first electrodes AE. The pixel defining layer PDL may define an emission area EA. Specifically, the emission area EA may be defined by an opening PDL-OP of the pixel defining layer PDL. The pixel defining layer PDL may include an organic insulating material, such as an acrylic-based material or benzocyclobutene (BCB).

The thin-film encapsulation layer TFE may be disposed on the second electrode CE. Although not illustrated, the thin-film encapsulation layer TFE may have a multilayer structure in which at least one organic encapsulation layer and at least one inorganic encapsulation layer are alternately stacked. The thin-film encapsulation layer TFE may protect a display from external moisture penetration.

The organic encapsulation layer may provide a flatter base surface. Thus, even when the touch sensing layer 300 to be described below is formed through a continuous process, a defect rate may be reduced.

The touch sensing layer 300 may be disposed on the thin-film encapsulation layer TFE. The touch sensing layer 300 may be configured to sense external input, such as a touch of an object (e.g., a finger or a stylus pen), so that the display device 1 may obtain coordinate information corresponding to a touch position. The touch sensing layer 300 may include a touch electrode and trace lines connected to the touch electrode. In the disclosure, a method of operating the touch sensing layer 300 is not particularly limited. For example, the touch sensing layer 300 may be configured to sense external input in a mutual capacitance method or a self-capacitance method.

The touch sensing layer 300 may be disposed on the thin-film encapsulation layer TFE. In an embodiment, the touch sensing layer 300 may be directly disposed on the thin-film encapsulation layer TFE. The expression “A is directly disposed on B” as used herein means that no separate adhesive layer or adhesive member is disposed between element A and element B. After element A is formed, element B may be formed through a continuous process on a base surface provided by element A. In an embodiment, the touch sensing layer 300 may be formed separately and then bonded to the thin-film encapsulation layer TFE through an adhesive layer, such as an optically clear adhesive.

The touch sensing layer 300 may include the first touch electrode MTL1, the first insulating layer 310, and the second touch electrode MTL2. The first touch electrode MTL1 may be directly disposed on the thin-film encapsulation layer TFE. In an embodiment, a planarization layer or the like may be further disposed on the thin-film encapsulation layer TFE. The planarization layer may include an insulating material that planarizes the thin-film encapsulation layer TFE. For example, the display device 1 may further include an interlayer insulating layer ILD disposed on the thin-film encapsulation layer TFE.

The first touch electrode MTL1 may be disposed to correspond between the first electrodes AE. Because an area where the first electrodes AE are disposed is a pixel area where an image is displayed to the outside, the first touch electrode MTL1 may be disposed in an area between the first electrodes AE, that is, an area where the first electrodes AE are not disposed.

The first touch electrode MTL1 may be a wiring for a touch screen. That is, the touch screen may include a plurality of sensor units, and the first touch electrode MTL1 may function as a connection wiring that connects the sensor units to each other. Therefore, the first touch electrode MTL1 may include a conductive metal material.

The first insulating layer 310 may be disposed on the first touch electrode MTL1. The first insulating layer 310 may electrically insulate the second touch electrode MTL2 and the first touch electrode MTL1 from each other. The first insulating layer 310 may include an insulating material. For example, the first insulating layer 310 may include an inorganic insulating material, such as silicon oxide, silicon nitride, or silicon oxynitride, or may include an organic insulating material, such as an acrylic-based organic material or BCB.

The second touch electrode MTL2 may be disposed on the first insulating layer 310. The second touch electrode MTL2 may be formed to correspond to the first touch electrode MTL1. Like the first touch electrode MTL1, the second touch electrode MTL2 may be disposed to correspond between the first electrodes AE. The first touch electrode MTL1 and the second touch electrode MTL2 may be electrically connected to each other through a contact hole formed in the first insulating layer 310.

The second touch electrode MTL2 may be a wiring for a touch screen, like the first touch electrode MTL1. That is, the touch screen may include a plurality of sensor units, and the second touch electrode MTL2 may function as a connection wiring that connects the sensor units to each other. Therefore, the second touch electrode MTL2 may include a conductive metal material.

Referring again to FIGS. 4 and 5, the display device may include a first emission area EA1, a second emission area EA2, and a third emission area.

The emission area may be defined by an opening PDL-OP of the pixel defining layer PDL. The pixel defining layer PDL may define the first to third emission areas EA1, EA2, and EA3. The pixel defining layer PDL may separate and insulate the first electrodes AE of the light-emitting elements from each other. The pixel defining layer PDL may include a light-absorbing material and may prevent light reflection.

The pixel defining layer PDL that defines the emission area may form a separation distance between different emission areas. That is, as the width of the pixel defining layer PDL between one emission area and another emission area increases, the separation distance between the emission areas may increase.

To further explain this, the width of the pixel defining layer PDL surrounding the light-emitting elements may vary. The separation distance between one light-emitting element and another light-emitting element may be different from the separation distance between one light-emitting element and further another light-emitting element.

Light-emitting elements configured to emit pieces of light of different wavelengths may be respectively disposed in the first to third emission areas EA1, EA2, and EA3. As an example, a first light-emitting element configured to emit red light may be disposed in the first emission area EA1, a second light-emitting element configured to emit green light may be disposed in the second emission area EA2, and a third light-emitting element configured to emit blue light may be disposed in the third emission area EA3. Emission layers of the first light-emitting element, the second light-emitting element, and the third light-emitting element may include different materials, and thus, the lifespans of the light-emitting elements may be different from each other. Therefore, the areas of the emission areas where the light-emitting elements are disposed may be different from each other.

That is, the first emission area EA1, the second emission area EA2, and the third emission area EA3 may have different areas. For example, the area of the second emission area EA2 where the second light-emitting element configured to emit green light is disposed may be greater than the area of the first emission area EA1 where the first light-emitting element configured to emit red light is disposed. The area of the third emission area EA3 where the third light-emitting element configured to emit blue light is disposed may be greater than the area of the second emission area EA2. However, the concept of the disclosure is not limited thereto, and the relationship between the sizes of the first emission area EA1, the second emission area EA2, and the third emission area EA3 may be different.

Accordingly, the emission areas may be disposed by taking into account the respective areas thereof, and the width of the pixel defining layer PDL surrounding the respective emission areas may vary depending on the arranged structure.

As illustrated in FIG. 4, a separation distance D1 between the first emission area EA1 and the second emission area EA2 may be equal to or similar to a separation distance D3 between the first emission area EA1 and the third emission area EA3.

The separation distance D1 between the first emission area EA1 and the second emission area EA2 may be equal to or similar to a separation distance D4 between the second emission area EA2 and the third emission area EA3.

That is, the separation distance D1 between the first emission area EA1 and the second emission area EA2, the separation distance D3 between the first emission area EA1 and the third emission area EA3, and the separation distance D4 between the second emission area EA2 and the third emission area EA3 may be equal to or similar to each other.

A separation distance D2 between one third emission area EA3 and another third emission area EA3 may be greater than the separation distance D1 between the first emission area EA1 and the second emission area EA2, the separation distance D3 between the first emission area EA1 and the third emission area EA3, or the separation distance D4 between the second emission area EA2 and the third emission area EA3.

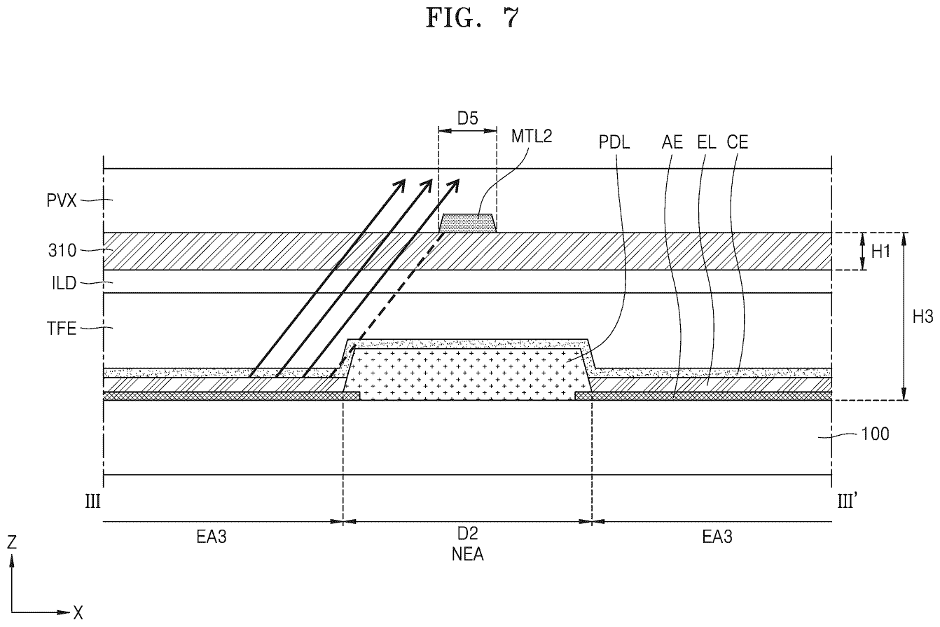

FIG. 5 is a schematic enlarged view of a region A of FIG. 4, and FIG. 6 is a schematic cross-sectional view illustrating an example of the cross-section of the display device taken along line II-II′ of FIG. 5. FIG. 7 is a schematic cross-sectional view illustrating an example of the cross-section of the display device taken along line III-III′ of FIG. 5. The solid arrows or dashed arrows shown in FIGS. 7 to 11 schematically represent the path of light emitted from the emission area.

Referring to FIGS. 5 to 7, the second touch electrode MTL2 may be disposed on the light-emitting element layer 200 to overlap the pixel defining layer PDL. Specifically, the second touch electrode MTL2 may be disposed on the first insulating layer 310 to overlap the pixel defining layer PDL.

Because the second touch electrode MTL2 is disposed on the light-emitting element layer 200, light occlusion by the second touch electrode MTL2 may occur when a viewing angle increases.

Because the second touch electrode MTL2 is apart from the light-emitting element layer 200 to some extent, a part of light emitted laterally from the emission area may be blocked.

The second touch electrode MTL2 may be disposed to surround at least a portion of each of the first emission area EA1, the second emission area EA2, and the third emission area EA3.

The second touch electrode MTL2 may be disposed to pass through the center between the emission areas. To further explain this, the distance between one emission area and the second touch electrode MTL2 adjacent thereto may be equal to the distance between the second touch electrode MTL2 and another emission area adjacent thereto.

At this time, as the width of the pixel defining layer PDL increases, the separation distance from the second touch electrode MTL2 to the emission area may increase.

Therefore, as the width of the pixel defining layer PDL increases, a difference in degree of light occlusion by the second touch electrode MTL2 may occur when a viewing angle increases.

Specifically, referring to FIG. 4, there may be an area where the width of the pixel defining layer PDL in the X-axis direction is different from the width of the pixel defining layer PDL in the Y-axis direction. For example, the distance D2 between the third emission areas EA3 may be greater than the distance D4 between the second emission area EA2 and the third emission area EA3. Therefore, the distance from the second touch electrode MTL2 to the third emission area EA3 in the area corresponding to the distance D2 may be greater than the distance from the second touch electrode MTL2 to the third emission area EA3 in the area corresponding to the distance D4.

As described above, because the third light-emitting element configured to emit blue light is disposed in the third emission area EA3, the amount by which the luminance for the blue color decreases as the viewing angle increases may be greater in the X-axis direction than in the Y-axis direction. The light occlusion phenomenon by the second touch electrode MTL2 of the third emission area EA3 may occur more in the X-axis direction than in the Y-axis direction.

As described above, the amounts of pieces of light emitted laterally from the light-emitting elements disposed in the emission areas may be different from each other, which may cause a difference in viewing angle or a color change according to an azimuth, and optical characteristics of the display device required by a customer may not be satisfied.

The display device according to an embodiment may improve the problem of a difference in side visibility that occurs when the width of the pixel defining layer PDL is different as described above. This is described in detail with reference to the accompanying drawings.

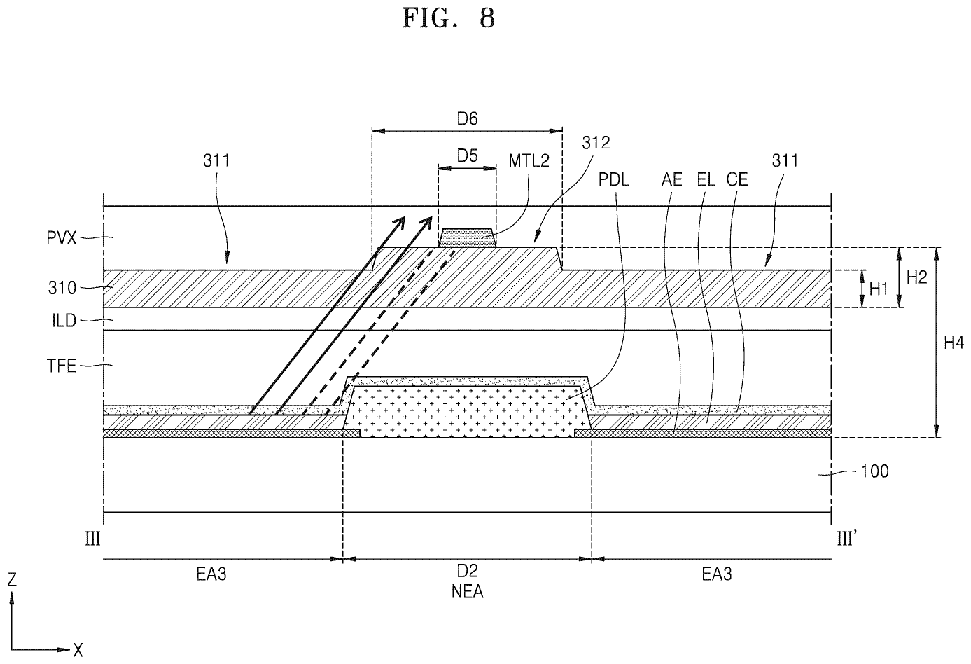

FIG. 8 is a schematic cross-sectional view illustrating an example of the cross-section of the display device taken along line III-III′ of FIG. 5.

In an embodiment, the distance between one surface, e.g., the upper surface, of the substrate 100 and the second touch electrode MTL2 may vary depending on the width of the pixel defining layer PDL on which the second touch electrode MTL2 is disposed. To further explain this, the height at which the second touch electrode MTL2 is disposed on the pixel defining layer PDL may vary depending on the width of the pixel defining layer PDL on which the second touch electrode MTL2 is disposed.

Specifically, as the width of the pixel defining layer PDL increases, the distance between the second touch electrode MTL2 disposed on the pixel defining layer PDL and one surface of the substrate 100 may increase.

For example, referring to FIGS. 6 and 8, the width D2 of the pixel defining layer PDL between the third emission area EA3 and the third emission area EA3 may be wider than the width D1 of the pixel defining layer PDL between the first emission area EA1 and the second emission area EA2, as illustrated in FIGS. 6 and 8. At this time, the distance H4 between the substrate 100 and the second touch electrode MTL2 corresponding to the width D2 of the pixel defining layer PDL between the third emission area EA3 and the third emission area EA3 may be greater than the distance H3 between the substrate 100 and the second touch electrode MTL2 corresponding to the width D1 of the pixel defining layer PDL between the first emission area EA1 and the second emission area EA2.

In the display device according to an embodiment, because the first insulating layer 310 is formed to be thick, the height at which the second touch electrode MTL2 is disposed may be formed to be high.

In an embodiment, the first insulating layer 310 may include a first area 311 corresponding to the emission area and a second area 312 corresponding to the pixel defining layer PDL, and the thickness H2 of the second area 312 may be different from the thickness H1 of the first area 311. That is, by increasing the thickness H2 of the second area 312, the height of the second touch electrode MTL2 disposed on the second area 312 may be increased.

By increasing the thickness H2 of the second area 312 of the first insulating layer 310, the distance H4 between one surface of the substrate 100 and the second touch electrode MTL2 may be increased.

Accordingly, by increasing the degree of light occlusion by the second touch electrode MTL2, the difference from the degree of light occlusion by the second touch electrode MTL2 disposed on another pixel defining layer PDL may be reduced.

To further explain this, the thickness of the first insulating layer 310 corresponding to the area where the second touch electrode MTL2 is disposed may be proportional, e.g., have a constant ratio, to the width of the pixel defining layer PDL in the area corresponding to the second touch electrode MTL2.

The maximum thickness of the first insulating layer 310 may be equal to or less than twice the minimum thickness. Specifically, the thickness of the second area 312 of the first insulating layer 310 may be equal to or less than twice the thickness of the first area 311 of the first insulating layer 310.

A half-tone mask may be used to form the first insulating layer 310. For example, after a photoresist layer is formed on an insulating material layer, a half-tone mask is disposed on the photoresist layer. The half-tone mask may include a light blocking area, a light transmission area, and a semi-transmission area.

After the photoresist layer is formed on the insulating material layer, the half-tone mask may be used to form a photoresist pattern in which a thickness of an area corresponding to the second area 312 is greater than a thickness of an area not corresponding to the second area 312. The first insulating layer 310 may be formed by selectively etching the insulating material layer using the photoresist pattern as a mask.

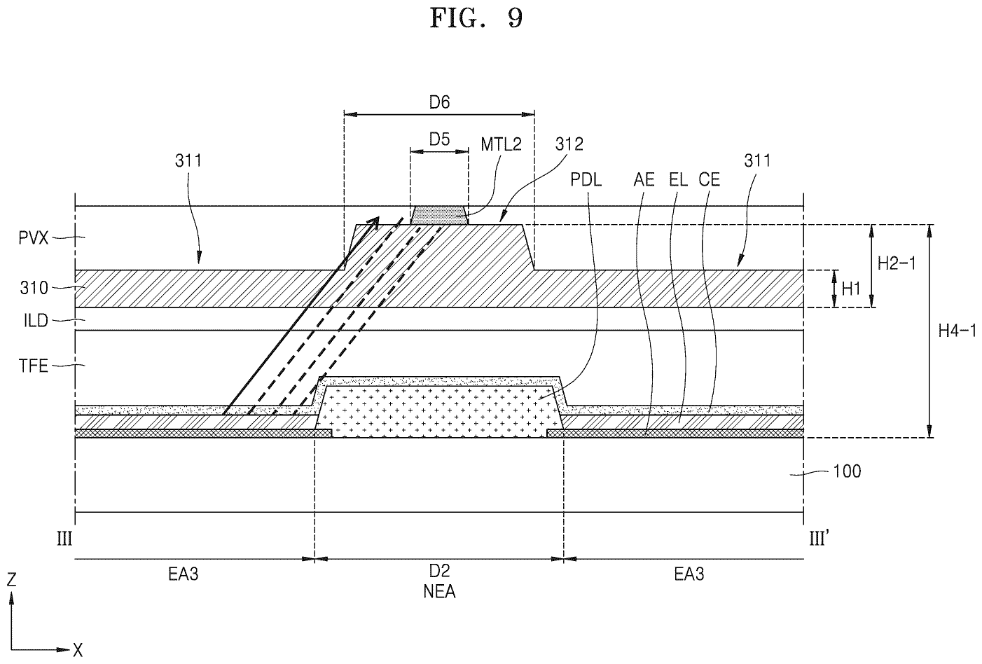

FIG. 9 is a schematic cross-sectional view illustrating an example of the cross-section of the display device taken along line III-III′ of FIG. 5.

Referring to FIGS. 7 to 9, a thickness H2-1 of a second area 312 according to the example illustrated in FIG. 9 may be greater than the thickness H2 of the second area 312 according to the example illustrated in FIG. 8. Accordingly, by further increasing the thickness of the second area 312 of the first insulating layer 310, the height at which the second touch electrode MTL2 is disposed may be further increased.

The distance H4-1 between the second touch electrode MTL2 disposed on the second area 312 and one surface of the substrate 100 may be greater than the distance H4 between the second touch electrode MTL2 and one surface of the substrate 100 as described above.

As the distance between the second touch electrode MTL2 and the substrate 100 increases, the effect of blocking light emitted laterally from the emission area may increase.

The display device according to an embodiment may further include the protective layer PVX covering the second touch electrode MTL2 and the first insulating layer 310. The refractive index of the protective layer PVX may be greater than the refractive index of the first insulating layer 310. Hereinafter, a structure in which the refractive index of the first insulating layer 310 and the refractive index of the protective layer PVX are differentially applied is described.

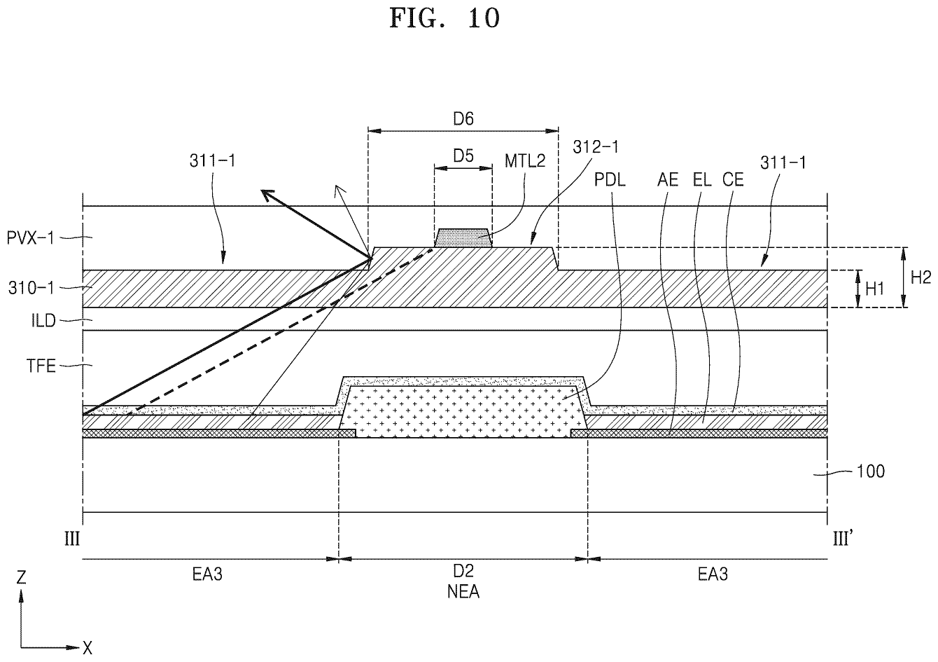

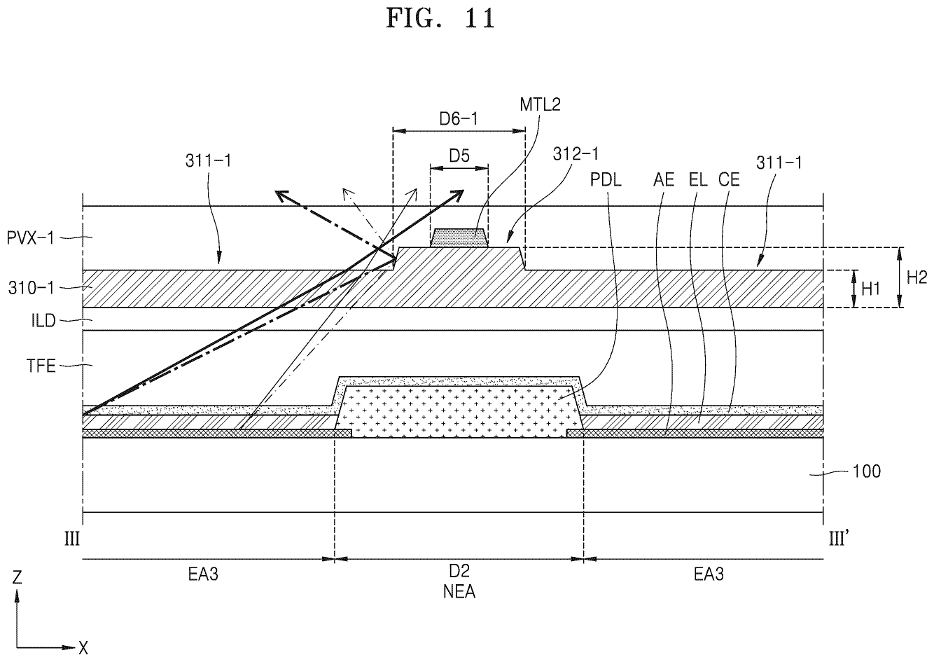

FIG. 10 is a schematic cross-sectional view illustrating an example of the cross-section of the display device taken along line III-III′ of FIG. 5, and FIG. 11 is a schematic cross-sectional view illustrating an example of the cross-section of the display device taken along line III-III′ of FIG. 5.

In the display device according to an embodiment, a refractive index of a protective layer PVX-1 may be higher than a refractive index of a first insulating layer 310-1. For example, when the refractive index of the first insulating layer 310-1 is 1.5, the refractive index of the protective layer PVX-1 may be 1.5 to 1.7, which is greater than the refractive index of the first insulating layer 310-1.

The first insulating layer 310-1 may include at least one of an inorganic material or an organic material. In some embodiments, the protective layer PVX-1 may include an organic material. The inorganic material may include one or more materials selected from silicon nitride (SiNₓ), silicon oxide (SiOₓ), silicon oxynitride (SiOₓN_{y}), and aluminum oxide (AlOₓ). The organic material may include one or more materials selected from acrylic resin, epoxy resin, phenol resin, polyamide resin, and polyimide resin. However, the embodiments are not limited thereto.

As illustrated in FIG. 10, when a second area 312-1 of the first insulating layer 310-1 is formed to be thicker than a first area 311-1, a width D6 of the second area 312-1 may be defined. That is, the second area 312-1 may be a protruding area having a certain width D6. When the refractive index of the protective layer PVX-1 is higher than the refractive index of the first insulating layer 310-1, light emitted from the emission area and traveling may be refracted at the boundary between the first insulating layer 310-1 and the protective layer PVX-1 after passing through the first insulating layer 310-1, and thus, the path of the light may be changed.

For example, total reflection may occur when light having passed through the protective layer PVX-1 encounters the second area 312-1 of the first insulating layer 310-1. Through this phenomenon, the degree of light occlusion by the second touch electrode MTL2 and the first insulating layer 310-1 may be increased.

The width D6 of the second area 312-1 may be proportional to the width D2 of the pixel defining layer PDL. That is, as the width D2 of the pixel defining layer PDL increases, the width D6 of the second area 312-1 may increase.

The width D6 of the second area 312-1 may be equal to or greater than twice a width D5 of the second touch electrode MTL2 and equal to or less than the width D2 of the pixel defining layer PDL.

That is, when the width D6 of the second area 312-1, the width D5 of the second touch electrode MTL2, and the width D2 of the pixel defining layer PDL are respectively defined as w1, w2, and w3, the display device may satisfy the relationship of 2*w2≤w1≤w3.

Therefore, the display device according to the example illustrated in FIG. 10 may satisfy 2*D5≤D6≤D2.

The display device according to an embodiment may further suppress light output as the width D6 of the second area 312-1 increases.

Because the width D6 of the second area 312-1 according to the example illustrated in FIG. 10 is greater than the width D6-1 of the second area 312-1 according to the example illustrated in FIG. 11, the display device according to the example illustrated in FIG. 10 may further suppress light output.

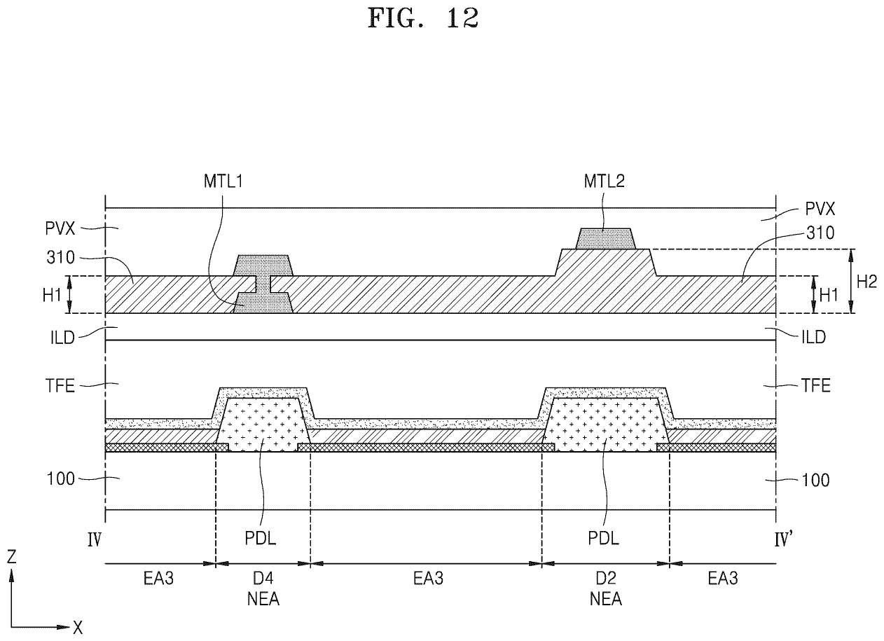

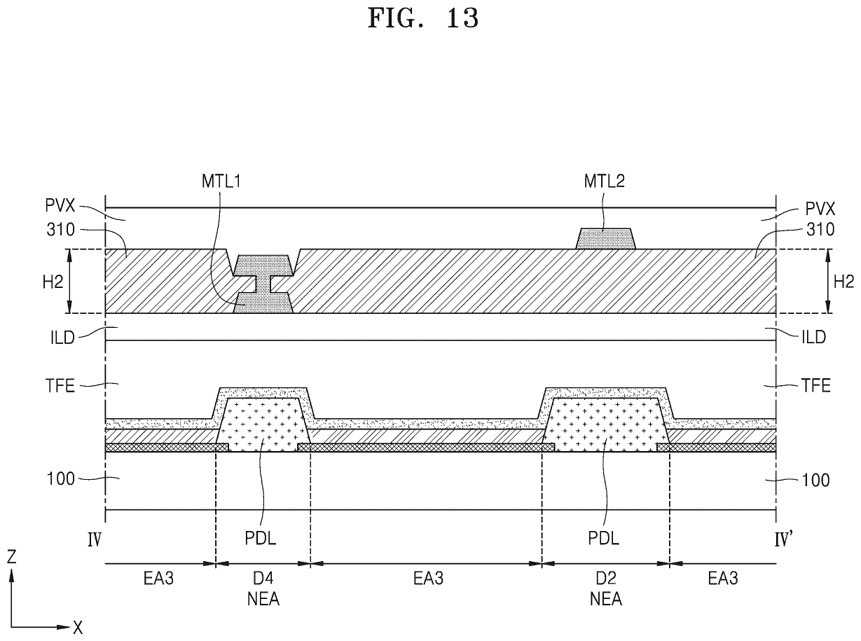

FIG. 12 is a schematic cross-sectional view illustrating an example of the cross-section of the display device taken along line IV-IV′ of FIG. 5, and FIG. 13 is a schematic cross-sectional view illustrating an example of the cross-section of the display device taken along line IV-IV′ of FIG. 5.

As described above, the distance D4 between the second emission area EA2 and the third emission area EA3 may be less than the distance D2 between one third emission area EA3 and another third emission area EA3. That is, the width of the pixel defining layer PDL may vary.

The first touch electrode MTL1 may be disposed on the interlayer insulating layer ILD and the first insulating layer 310 may be disposed on the first touch electrode MTL1.

The first touch electrode MTL1 may be disposed above the pixel defining layer PDL having a narrow width and the second touch electrode MTL2 may be disposed above the pixel defining layer PDL having a wide width.

The thickness H2 of an area of the first insulating layer 310 on which the second touch electrode MTL2 is disposed may be greater than the thickness H1 of another area of the first insulating layer 310.

Specifically, the thickness H2 of the first insulating layer 310 on a non-emission area NEA may be greater than the thickness of the first insulating layer 310 on the emission area EA.

In an embodiment, as illustrated in FIG. 13, the thickness H2 of the first insulating layer 310 may be increased in both the emission area EA and the non-emission area NEA.

Consequently, the second touch electrode MTL2, which is disposed on the area where the width of the pixel defining layer PDL is wide, may be positioned higher than the first touch electrode MTL1, which is disposed on the area where the width of the pixel defining layer PDL is relatively narrow. The second touch electrode MTL2 disposed on the area where the width of the pixel defining layer PDL is wide may be disposed in the area where the first insulating layer 310 is thick.

An embodiment may provide an electronic device that may include the above-described display device as a display module and may further include a memory and a processor.

The memory may store at least one command for sensing touch input.

The processor may be configured to operate with reference to the memory and sense a touch position based on sensing data sensed through the first touch electrode MTL1 and the second touch electrode MTL2.

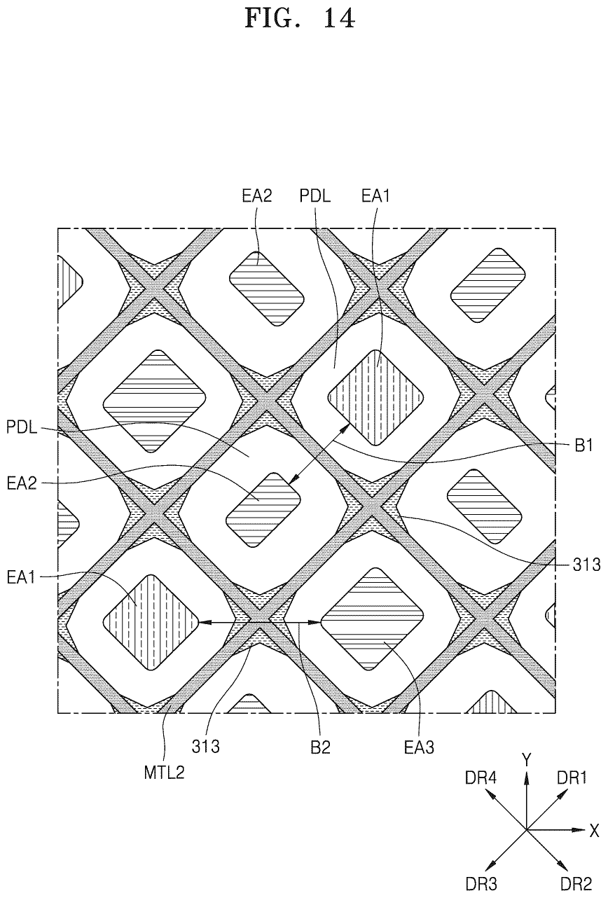

FIG. 14 is a schematic plan view of a display device according to an embodiment.

Hereinafter, a first direction DR1 may be a direction between the X-axis direction and the Y-axis direction, a second direction DR2 may be a direction between the direction opposite to the Y-axis direction and the X-axis direction, a third direction DR3 may be a direction opposite to the first direction DR1, and a fourth direction DR4 may be a direction opposite to the second direction DR2.

Each of first pixels may include a first emission area EA1 configured to emit light of a first color, a second emission area EA2 configured to emit light of a second color, and a third emission area EA3 configured to emit light of a third color. For example, the first color may be red, the second color may be green, and the third color may be blue.

The first emission area EA1 may be adjacent to the second emission area EA2 in the fourth direction DR4 or the third direction DR3. The third emission area EA3 may be adjacent to the second emission area EA2 in the second direction DR2 or the first direction DR1.

Each of the first emission area EA1, the second emission area EA2, and the third emission area EA3 may have a rhombic planar shape or a rectangular planar shape, but the disclosure is not limited thereto. Each of the first emission area EA1, the second emission area EA2, and the third emission area EA3 may have a polygonal, circular, or elliptical planar shape other than the rectangular planar shape. In addition, in FIG. 14, the area of the third emission area EA3 may be the largest and the area of the second emission area EA2 may be the smallest, but the disclosure is not limited thereto.

A pixel defining layer PDL defining the emission area may form a separation distance between different emission areas. That is, as the width of the pixel defining layer PDL disposed between one emission area and another emission area increases, the separation distance between the emission areas may increase.

To further explain this, the width of the pixel defining layer PDL surrounding each light-emitting element may vary. The separation distance between one light-emitting element and another light-emitting element may be different from the separation distance between one light-emitting element and further another light-emitting element.

Specifically, as illustrated in FIG. 14, a distance B1 between the first emission area EA1 and the second emission area EA2 may be shorter than a distance B2 between the first emission area EA1 and the third emission area EA3.

That is, the distance between adjacent emission areas in the X-axis or Y-axis direction may be longer than the distance between adjacent emission areas in the first to fourth directions DR1-DR4.

Accordingly, the width of the pixel defining layer PDL surrounding the emission area may vary and the degree of light output suppression by the second touch electrode MTL2 may vary depending on the width of the pixel defining layer PDL on which the second touch electrode MTL2 is disposed.

Hereinafter, a result of an experiment on a change in viewing angle while varying the thickness of the first insulating layer 310 in an area 313 corresponding to distance B2 is described.

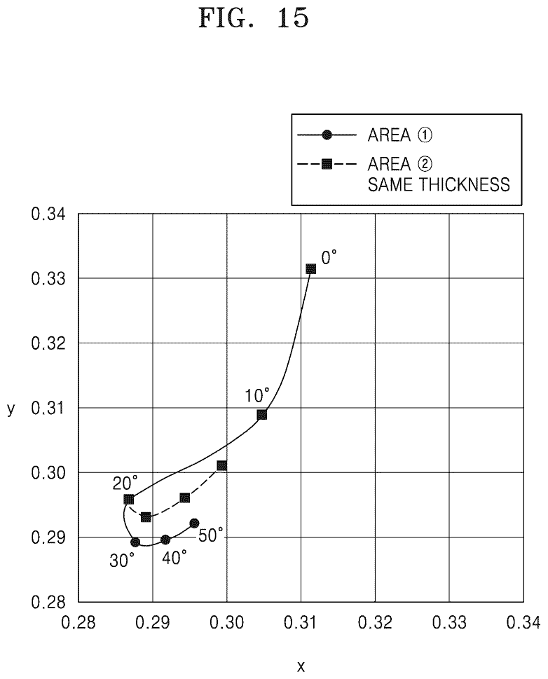

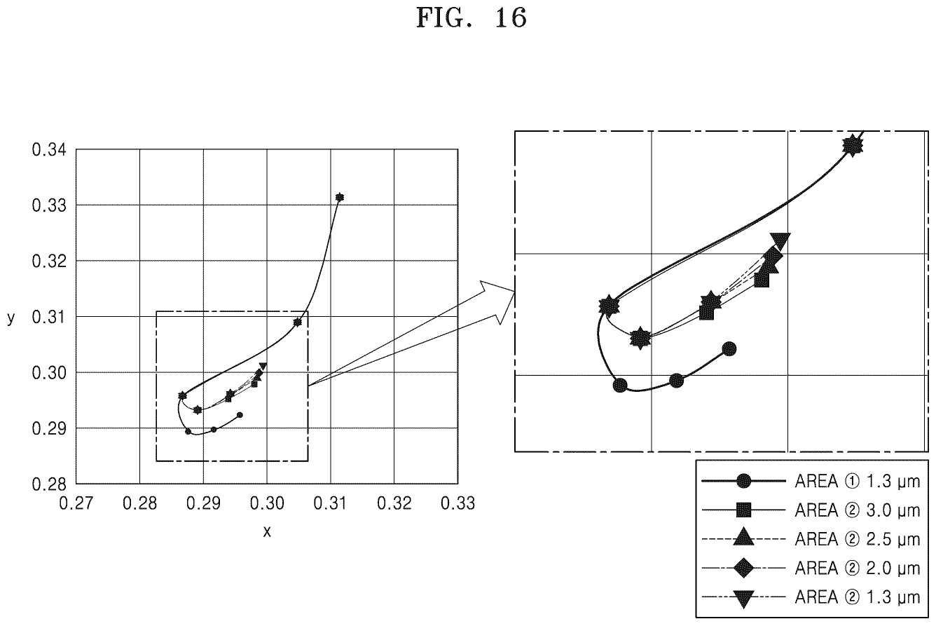

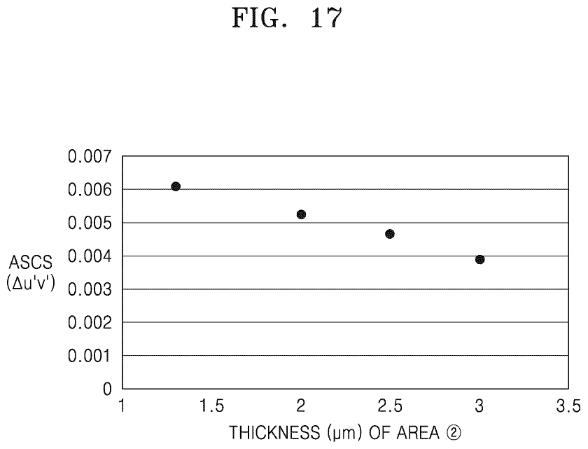

FIG. 15 is a graph showing color coordinates with respect to a measurement angle of white light in a display device according to a comparative example, and FIG. 16 is a graph showing color coordinates with respect to a measurement angle of white light in a display device according to an embodiment. FIG. 17 is a graph showing ASymmetry Color Shift (ASCS) with respect to a change in thickness of a first insulating layer in a display device according to an embodiment.

The color coordinates in FIGS. 15 and 16 are enlarged views of a portion of the CIE 1931 xyz color coordinates, and an angle was measured based on a direction perpendicular to the top surface of the display device (z direction).

An area corresponding to distance B1 is indicated as area \textcircled{1} and an area corresponding to distance B2 is indicated as area \textcircled{2}.

In the display device according to the comparative example, the first insulating layer 310 was formed to have the same thickness of 1.3 μm in area \textcircled{1} and area \textcircled{2}.

Referring to FIG. 15, it may be confirmed that, when the color coordinates of white light of the display device were measured while increasing a slope by 10 degrees in a direction perpendicular to the top surface of the substrate (z direction), there is a difference in color change between area \textcircled{1} and area \textcircled{1} at a slope of 30 degrees or more.

Referring to FIG. 16, it may be confirmed that, as the thickness of the first insulating layer 310 in area \textcircled{2} increases, a color change at high angles of area \textcircled{2} and area \textcircled{1} decreases.

In addition, referring to FIG. 17, it may be confirmed that, as the thickness of the first insulating layer 310 in area \textcircled{2} increases, an ASymmetry Color Shift (ASCS) value decreases.

That is, by increasing the thickness of the first insulating layer 310 and thus increasing the height at which the second touch electrode MTL2 is disposed, the problem of a difference in viewing angle or a color change according to azimuth may be improved.

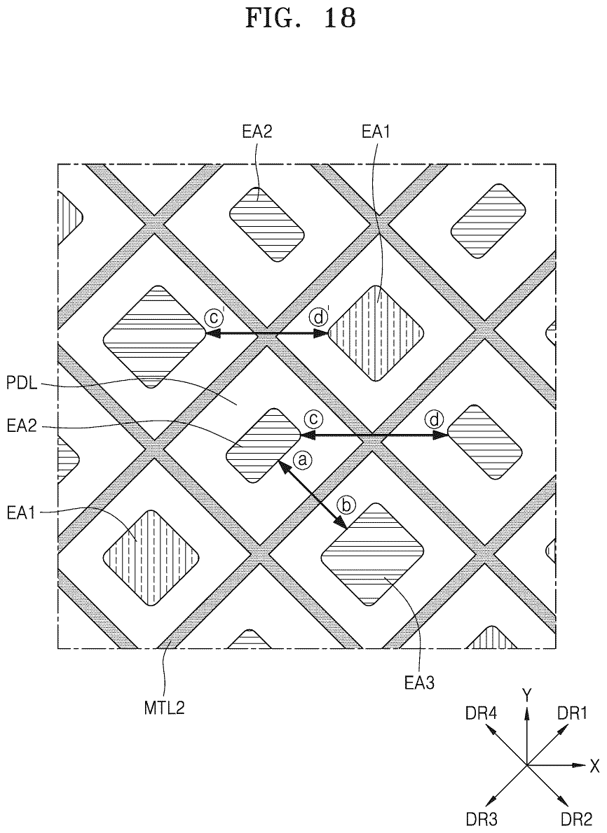

FIG. 18 is a diagram for comparing and describing distances between emission areas in the display device of FIG. 14.

Referring to FIG. 18, because a first emission area EA1, a second emission area EA2, and a third emission area EA3 are formed to have different areas, separation distances between the emission areas may be formed differently. As described above, emission layers of a first light-emitting element, a second light-emitting element, and a third light-emitting element may include different materials, and thus, the lifespans of the light-emitting elements may be different from each other. Therefore, the areas of the emission areas where the light-emitting elements are disposed may be different from each other.

That is, the first emission area EA1, the second emission area EA2, and the third emission area EA3 may have different areas. For example, the area of the first emission area EA1 in which the first light-emitting element configured to emit red light is disposed may be greater than the area of the second emission area EA2 in which the second light-emitting element configured to emit green light is disposed, and the area of the third emission area EA3 in which the third light-emitting element configured to emit blue light is disposed may be greater than the area of the first emission area EA1.

The distance between the second emission area EA2 and the third emission area EA3 adjacent to each other is represented by the distance \textcircled{a}-\textcircled{b}, the distance between two adjacent second emission areas EA2 is represented by the distance \textcircled{c}-\textcircled{d}, and the distance between the third emission area EA3 and the first emission area EA1 adjacent to each other is represented by the distance \textcircled{c}′-\textcircled{d}′. The distance \textcircled{c}-\textcircled{d} is greater than the distance \textcircled{a}-\textcircled{b}, and the distance \textcircled{c}-\textcircled{d} is greater than the distance \textcircled{c}′-\textcircled{d}′.

Accordingly, as illustrated, the width of the pixel defining layer PDL between two second emission areas EA2 may be greater than the width of the pixel defining layer PDL between the second emission area EA2 and the third emission area EA3, and the width of the pixel defining layer PDL between two second emission area EA2 may be greater than the width of the pixel defining layer PDL between the third emission area EA3 and the first emission area EA1.

Accordingly, the display device according to an embodiment may be formed so that the first insulating layer 310 has different thicknesses in the respective areas. The thickness of the first insulating layer 310 may be determined according to the material properties and process distribution of the light-emitting element, the physical properties of the thin-film encapsulation layer TFE, and the width of the second touch electrode MTL2.

Each of the embodiments described above may be implemented independently, but the structure of each of the embodiments may be applied in combination to other embodiments.

The disclosure has been described with reference to the embodiments illustrated in the drawings, but this is only an example. It will be understood by those of ordinary skill in the art that various modifications and equivalents may be made thereto. Accordingly, the true technical protection scope of the disclosure should be defined by the technical spirit of the appended claims.

Specific executions described in the embodiments are an embodiment, which does not limit the scope of the embodiments in any way. In addition, when there is no specific mention such as “essential,” “important,” etc., it may not be a necessary component for the application of the disclosure.

The use of the term “the” and similar demonstratives in the specification of the embodiments (in particular, the claims) is to be construed to cover both the singular and the plural. In addition, when a range is described in the embodiments, it includes the inventive concept to which individual values within the range are applied (unless otherwise indicated herein). This is the same as stating each individual value constituting the above range in the detailed description. Finally, operations constituting methods according to embodiments may be performed in any suitable order unless otherwise indicated herein or otherwise clearly contradicted by context. The embodiments are not necessarily limited by the order of description of operations. The use of any and all examples or exemplary terms provided in the embodiments is simply intended to describe the embodiments in detail, and the scope of the embodiments is not limited by the examples or exemplary terms unless otherwise claimed. In addition, it will be understood by those of ordinary skill in the art that various modifications, combinations and changes may be made according to design conditions and factors within the scope of the appended claims or equivalents thereof.

According to an embodiment, the effect of improving the side visibility of the display device may be obtained.

However, such an effect is only an example, and the effect of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a light-emitting element layer disposed on the substrate, the light-emitting element layer comprising a plurality of emission areas and a pixel defining layer defining the plurality of emission areas;
a first touch electrode disposed on the light-emitting element layer to overlap the pixel defining layer;
a first insulating layer disposed on the first touch electrode and the light-emitting element layer; and
a second touch electrode disposed on the first insulating layer to overlap the pixel defining layer,
wherein a distance between one surface of the substrate and the second touch electrode varies depending on a width of the pixel defining layer on which the second touch electrode is disposed.

2. The display device of claim 1, wherein the width of the pixel defining layer is defined as a distance between one emission area and another adjacent emission area, and
a thickness of the first insulating layer corresponding to an area where the second touch electrode is disposed is proportional to the width of the pixel defining layer in an area corresponding to the second touch electrode.

3. The display device of claim 1, wherein the first insulating layer comprises a first area corresponding to the plurality of emission areas and a second area corresponding to the pixel defining layer, and
a thickness of the second area is different from a thickness of the first area.

4. The display device of claim 3, further comprising a protective layer covering the second touch electrode and the first insulating layer,
wherein a refractive index of the protective layer is higher than a refractive index of the first insulating layer.

5. The display device of claim 4, wherein a width of the second area is proportional to the width of the pixel defining layer.

6. The display device of claim 5, wherein the width of the second area is equal to or greater than twice a width of the second touch electrode and equal to or less than the width of the pixel defining layer.

7. The display device of claim 1, further comprising an encapsulation layer covering the light-emitting element layer,
wherein the first touch electrode is disposed on the encapsulation layer.

8. The display device of claim 1, wherein the plurality of emission areas comprises:
a first emission area configured to emit light of a first color;
a second emission area configured to emit light of a second color different from the first color; and
a third emission area configured to emit light of a third color different from the first and second colors,
wherein the first emission area, the second emission area, and the third emission area have different areas from each other.

9. The display device of claim 8, wherein the first emission area is configured to emit red light,
the second emission area is configured to emit green light,
the third emission area is configured to emit blue light,
the first emission area is disposed adjacent to the second emission area in a first direction, and
the third emission area is disposed adjacent to each of the first emission area and the second emission area in a second direction,
wherein the first direction and the second direction are different.

10. The display device of claim 8, wherein the width of the pixel defining layer between the first emission area and the third emission area or between the second emission area and the third emission area is narrower than the width of the pixel defining layer between the third emission area and another third emission area.

11. The display device of claim 1, wherein a maximum thickness of the first insulating layer is equal to or less than twice a minimum thickness of the first insulating layer.

12. An electronic device comprising:
a display module comprising:
a light-emitting element layer comprising a plurality of emission areas and a pixel defining layer defining the plurality of emission areas;
a first touch electrode disposed on the light-emitting element layer to overlap the pixel defining layer;
a first insulating layer disposed on the first touch electrode and the light-emitting element layer; and
a second touch electrode disposed on the first insulating layer to overlap the pixel defining layer, wherein a height at which the second touch electrode is disposed varies depending on a width of the pixel defining layer on which the second touch electrode is disposed;
a memory configured to store at least one command for sensing touch input; and
a processor configured to operate with reference to the memory and sense a touch position based on sensing data sensed through the first touch electrode and the second touch electrode.

13. The electronic device of claim 12, wherein the width of the pixel defining layer is defined as a distance between one emission area and another adjacent emission area, and
a thickness of the first insulating layer corresponding to an area where the second touch electrode is disposed is proportional to the width of the pixel defining layer in an area corresponding to the second touch electrode.

14. The electronic device of claim 12, wherein the first insulating layer comprises a first area corresponding to the plurality of emission areas and a second area corresponding to the pixel defining layer, and
a thickness of the second area is different from a thickness of the first area.

15. The electronic device of claim 14, further comprising a protective layer covering the second touch electrode and the first insulating layer,
wherein a refractive index of the protective layer is higher than a refractive index of the first insulating layer.

16. The electronic device of claim 15, wherein a width of the second area is proportional to the width of the pixel defining layer.

17. The electronic device of claim 16, wherein the width of the second area is equal to or greater than twice a width of the second touch electrode and equal to or less than the width of the pixel defining layer.

18. The electronic device of claim 12, wherein the plurality of emission areas comprises:
a first emission area configured to emit light of a first color;
a second emission area configured to emit light of a second color different from the first color; and
a third emission area configured to emit light of a third color different from the first and second colors,
wherein the first emission area, the second emission area, and the third emission area have different areas from each other.

19. The electronic device of claim 18, wherein the first emission area is configured to emit red light,
the second emission area is configured to emit green light,
the third emission area is configured to emit blue light,
the first emission area is disposed adjacent to the second emission area in a first direction, and
the third emission area is disposed adjacent to each of the first emission area and the second emission area in a second direction,
wherein the first direction and the second direction are different.

20. The electronic device of claim 18, wherein the width of the pixel defining layer between the first emission area and the third emission area or between the second emission area and the third emission area is narrower than the width of the pixel defining layer between the third emission area and another third emission area.
